(19) United States
(12) Patent Application Publication
(10) Pub. No.: US 2013/0081937 A1
(43) Pub. Date: Apr. 4, 2013

(54) BIT PATTERNED MAGNETIC MEDIA FABRICATED BY TEMPLATED GROWTH FROM A PRINTED TOPOGRAPHIC PATTERN

(71) Applicant: Thomas R. Albrecht, San Jose, CA (US)

(72) Inventor: Thomas R. Albrecht, San Jose, CA (US)

(73) Assignee: Hitachi Global Storage Technologies Netherlands B.V., Amsterdam (NL)

(21) Appl. No.: 13/370,131

(22) Filed: Feb. 9, 2012

Related U.S. Application Data
(63) Continuation-in-part of application No. 13/251,125, filed on Sep. 30, 2011.

(51) Int. Cl. C23C 14/34; C01B 13/14; B01J 19/12

(52) U.S. Cl. 204/157.5; 204/192.1

(57) ABSTRACT

A method for manufacturing a bit patterned magnetic media for magnetic data recording. The method includes patterning a topography that includes an array of raised regions separated by a recessed portion. The array can be patterned by micro-printing using a stamp that has raised islands. The raised regions can have a height of 1 to 5 nm as measured from the recessed region. A magnetic alloy and a non-magnetic segregant are then co-sputtered. The magnetic alloy preferentially grows over the raised portions and the non-magnetic segregant grow preferentially over the recessed region between the raised portions.

### RELATED APPLICATIONS

The present invention is a Continuation in Part of commonly assigned U.S. patent application Ser. No. 13/251,125, entitled FABRICATION OF BIT PATTERNED MEDIA USING MICROCONTACT PRINTING, which was filed on Sep. 30, 2011.

### FIELD OF THE INVENTION

The present invention relates to magnetic data recording and more particularly to bit patterned media and to a method for manufacturing such a media using a patterned topography to control oxide and magnetic layer formation during deposition.

### BACKGROUND OF THE INVENTION

A key component of a computer is an assembly that is referred to as a magnetic disk drive. The magnetic disk drive includes a rotating magnetic disk, write and read heads that are suspended by a suspension arm adjacent to a surface of the rotating magnetic disk and an actuator that swings the suspension arm to place the read and write heads over selected circular tracks on the rotating disk. The read and write heads are directly located on a slider that has an air bearing surface (ABS). When the slider rides on the air bearing, the write and read heads are employed for writing magnetic impressions to and reading magnetic impressions from the rotating disk. The read and write heads are connected to processing circuitry that operates according to a computer program to implement the writing and reading functions.

As the data density of magnetic recording systems increases, it becomes necessary to fit more bits of ever smaller size closer together on a magnetic media. When the data density becomes too large, the grains of the magnetic media become so small that they become thermally unstable. One way to mitigate this is to construct the media as a bit patterned media. Such a media includes individual isolated magnetic islands that are separated by non-magnetic material or non-magnetic spaces. Developments to produce such bit patterned media have proven to be expensive and time consuming for use in a manufacturing environment. In addition, the ability to construct such a bit patterned media at high data density has run in to manufacturing limitations such as with regard to the lithographic processes and other processes used to construct such a media. Therefore, there remains a need for a process for manufacturing a bit patterned media in a cost and time efficient manner that can produce a bit patterned media having a high data density.

### SUMMARY OF THE INVENTION

The present invention provides a method for manufacturing a magnetic media that includes forming a patterned topography that includes an array of raised regions surrounded by a recessed region; and simultaneously co-sputter depositing a magnetic alloy and a non-magnetic material.

The magnetic alloy advantageously grows over the raised regions and the non-magnetic segregant grows preferentially in the recessed region between the raised regions. The raised region is formed as an array that can include features formed as elliptical islands.

In another embodiment of the invention a magnetic media can be constructed by a method that includes depositing a seed layer and forming a stamp having a pattern formed thereon. The stamp is coated with a segregant promoter material, and the stamp is placed against the seed layer so as to print the segregant promoter material onto the seed layer. A co-sputtering of a magnetic material and a segregant material is then performed.

The segregant promoter can be a self-assembled monolayer material, which can be a hydrocarbon polymer with silane and thiol termination such as HS—(CH₂)ₙ—Si(X)₃, where n>2 and X is Cl or OCH₃. When this material is oxidized such as by ultraviolet (UV)/ozone exposure, the subsequent co-sputtering causes the magnetic material to grow preferentially (or selectively) over the seed layer and causes the non-magnetic segregant (e.g. oxide) to grow preferentially (or selectively) over the segregant promoter layer.

This process for forming a bit patterned media eliminates the need for costly, time consuming etching processes to define the location of magnetic islands on the media and also avoids potential damage to the magnetic media that might arise from the use of such etching.

These and other features and advantages of the invention will be apparent upon reading of the following detailed description of preferred embodiments taken in conjunction with the Figures in which like reference numerals indicate like elements throughout.

### BRIEF DESCRIPTION OF THE DRAWINGS

For a fuller understanding of the nature and advantages of this invention, as well as the preferred mode of use, reference should be made to the following detailed description read in conjunction with the accompanying drawings which are not to scale.

FIG. 1 is a schematic illustration of a disk drive system in which the invention might be embodied;

FIG. 2 is a top down view of a portion of a bit patterned media according to an embodiment of the invention;

FIG. 3 is a view of a magnetic media in an intermediate stage of manufacture, having a soft magnetic under-layer and a seed layer;

FIG. 4 is a view of a stamp for use in a method of the present invention;

FIG. 5 is a top down perspective view of the stamp of FIG. 4;

FIG. 6 is a view of the stamp of FIG. 5 with a layer of segregant promoter material coated thereon;

FIG. 7 is a view illustrating a stamping process wherein a segregant promoter material is selectively applied to the magnetic media under-layer and seed layer of FIG. 3;

FIG. 8 is a view of the magnetic media under-layer and seed layer with the segregant promoter layer selectively applied;

FIG. 9 is a top down view of the structure of FIG. 8;

FIG. 10 is a view of a magnetic media having a bit pattern formed thereon by a method of the present invention;

FIGS. 11 and 12 are views illustrating a possible method for manufacturing a stamp for use in a method according to the invention;

FIG. 13 is a cross sectional view of a substrate, soft under-layer, and exchange break layer, of a magnetic media formed in preparation for manufacturing a magnetic media according to an embodiment of the invention;

FIG. 14 is a cross sectional view of a magnetic media showing a patterned oxide layer;

FIG. 15 is a perspective view of a stamp prepared for patterning an oxide layer according to the alternate embodiment of the invention;

FIG. 16 is a top down view of the magnetic-Media of FIG. 14 showing the patterned oxide layer formed according to the alternate embodiment of the invention;

FIG. 17 is a cross sectional view of the magnetic media formed according to the alternate embodiment of the invention, showing a seed layer deposited over the patterned oxide layer;

FIG. 18 is as cross sectional view of the magnetic media formed according to the alternate embodiment of the invention showing magnetic islands and non-magnetic segregants grown by a templated, topographic pattern; and

FIG. 19 is a cross sectional view of the magnetic media formed according to the alternate embodiment of the invention showing an exchange coupling layer, capping layer and protective overcoat.

### DETAILED DESCRIPTION OF THE PREFERRED EMBODIMENTS

The following description is of the best embodiments presently contemplated for carrying out this invention. This description is made for the purpose of illustrating the general principles of this invention and is not meant to limit the inventive concepts claimed herein.

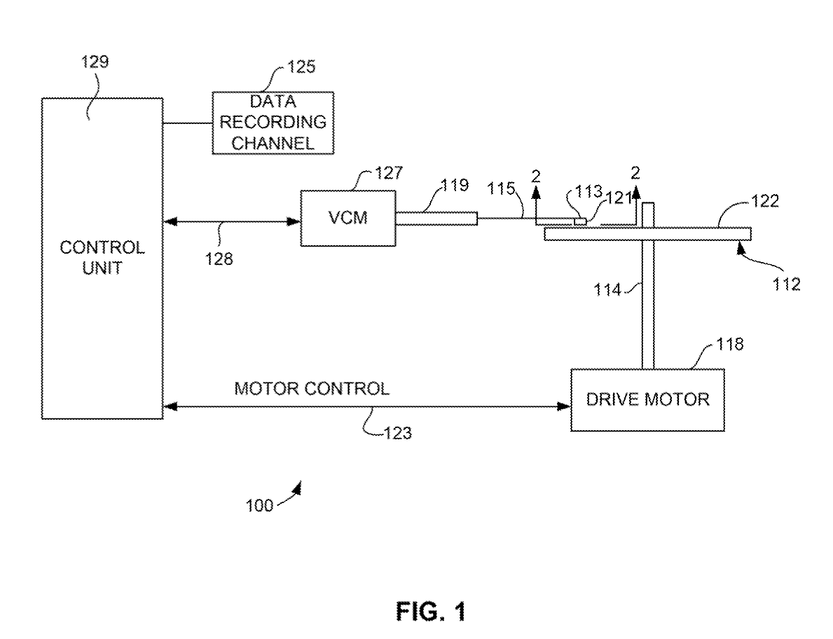

Referring now to FIG. 1, there is shown a disk drive 100 embodying this invention. As shown in FIG. 1, at least one rotatable magnetic disk 112 is supported on a spindle 114 and rotated by a disk drive motor 118. The magnetic recording on each disk is in the form of annular patterns of concentric data tracks (not shown) on the magnetic disk 112.

At least one slider 113 is positioned near the magnetic disk 112, each slider 113 supporting one or more magnetic head assemblies 121. As the magnetic disk rotates, slider 113 moves radially in and out over the disk surface 122 so that the magnetic head assembly 121 can access different tracks of the magnetic disk where desired data are written. Each slider 113 is attached to an actuator arm 119 by way of a suspension 115. The suspension 115 provides a slight spring force which biases slider 113 against the disk surface 122. Each actuator arm 119 is attached to an actuator means 127. The actuator means 127 as shown in FIG. 1 may be a voice coil motor (VCM). The VCM comprises a coil movable within a fixed magnetic field, the direction and speed of the coil movements being controlled by the motor current signals supplied by controller 129.

During operation of the disk storage system, the rotation of the magnetic disk 112 generates an air bearing between the slider 113 and the disk surface 122 which exerts an upward force or lift on the slider. The air bearing thus counter-balances the slight spring force of suspension 115 and supports slider 113 off and slightly above the disk surface by a small, substantially constant spacing during normal operation.

The various components of the disk storage system are controlled in operation by control signals generated by control unit 129, such as access control signals and internal clock signals. Typically, the control unit 129 comprises logic control circuits, storage means and a microprocessor. The control unit 129 generates control signals to control various system operations such as drive motor control signals on line 123 and head position and seek control signals on line 128. The control signals on line 128 provide the desired current profiles to optimally move and position slider 113 to the desired data track on disk 112. Write and read signals are communicated to and from write and read heads 121 by way of recording channel 125.

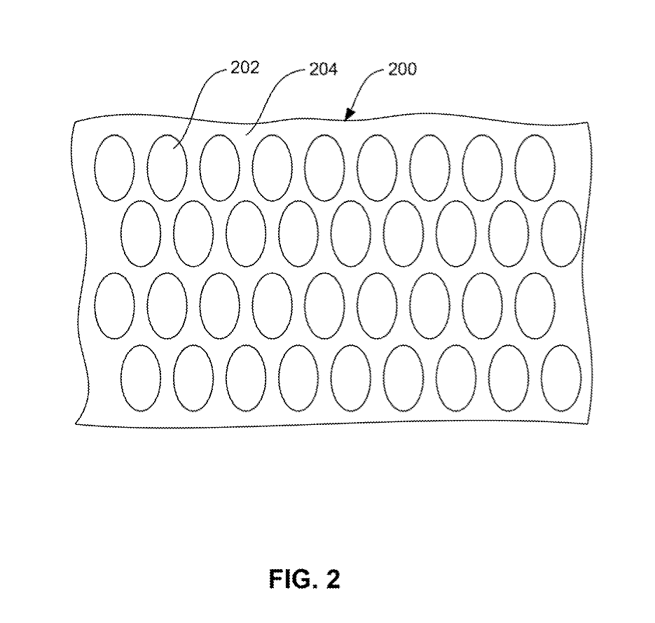

FIG. 2 shows a top down view of a portion of a magnetic media that can be constructed according to a method of the present invention. In FIG. 2 it can be seen that the magnetic media 200 has magnetic islands 202 that are separated by non-magnetic segregant material 204. The magnetic islands 202 can be constructed of a material such as an alloy containing cobalt and platinum, and the non-magnetic segregant can be an oxide such as SiO₂.

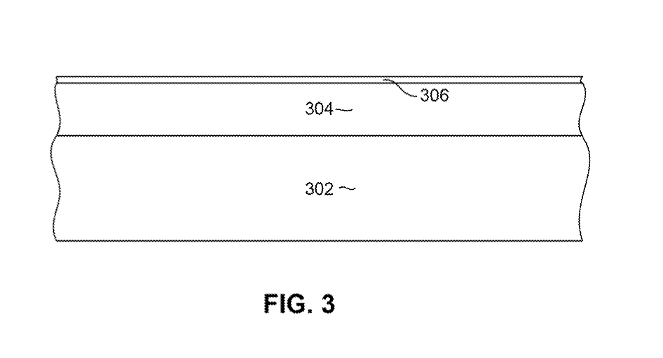

FIGS. 3-10 illustrate a method for manufacturing a magnetic media according to an embodiment of the invention. With particular reference to FIG. 3, a substrate 302 is provided. This substrate 302 can be a glass substrate or aluminum alloy that has been polished to have a very smooth surface. A soft magnetic layer 304 is deposited over the substrate 302. The soft magnetic layer 304 is a material having a low magnetic coercivity and may actually be constructed as a lamination of one or more magnetic layers separated by thin non-magnetic layers. After the soft magnetic layer 304 has been deposited over the substrate 302, a seed layer 306 is deposited over the soft magnetic layer 304. The seed layer is a material that is suitable for the growth of large-grain magnetic alloys thereon, and can be Ru deposited by low pressure sputter deposition. The seed layer 306 can also be a lamination of several layers.

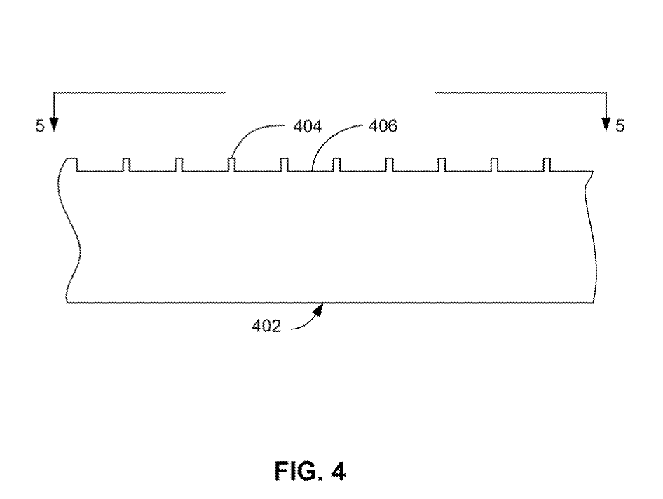

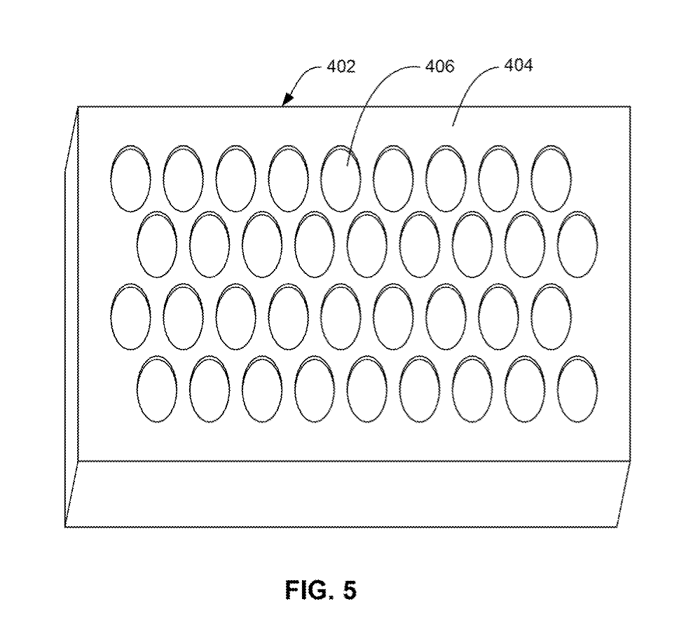

With reference to FIG. 4, a stamp 402 is formed having raised portions 404 and recessed portions 406. FIG. 5 shows a top down perspective view of the structure of FIG. 4, as seen from line 5-5 of FIG. 4. In FIG. 5 it can be seen that the recesses 406 can be formed as circular or elliptical recesses 406 that are separated by raised portions. These recesses 406 will define an area where a magnetic island will be formed on the magnetic media, as will be seen. Although the recesses 406 are shown as being elliptical in FIG. 5, this is by way of example. They could be formed in other shapes, such as circles or rectangles if desired.

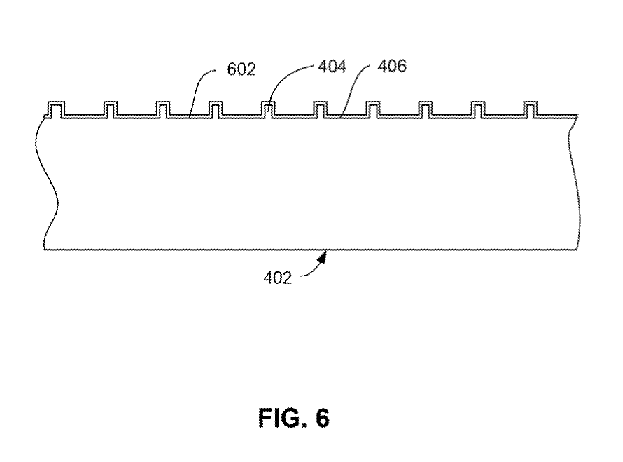

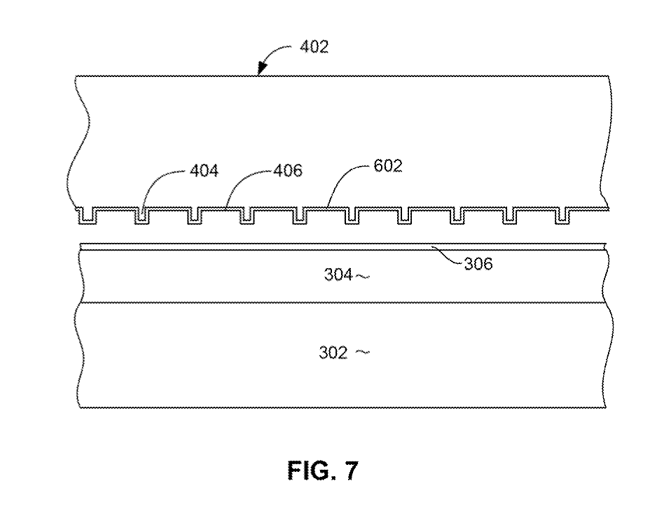

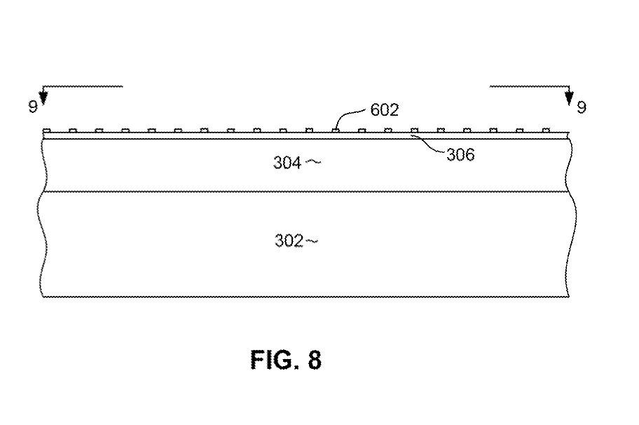

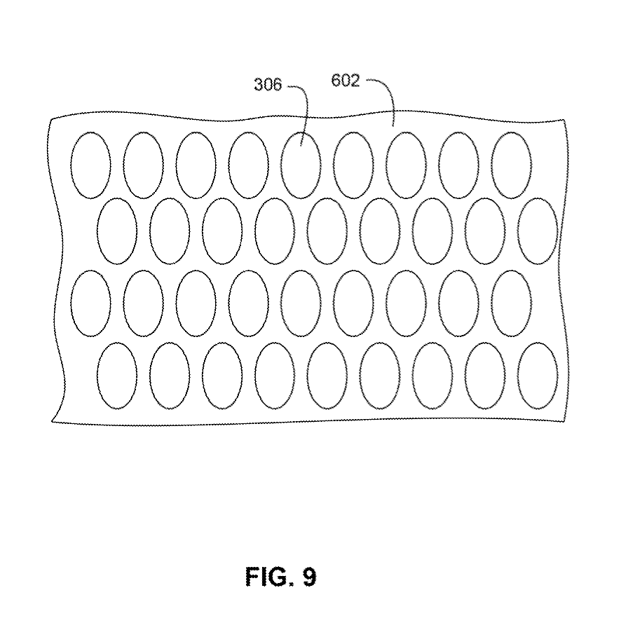

With reference now to FIG. 6, a very thin, continuous layer of a segregant promoter material 602 is coated onto the stamp 402. The segregant promoter material 602 is a material that causes the preferential growth of a segregant during sputter deposition. The segregant promoter material can be a material that can form an oxide like material. For example, the segregant promoter material 602 can be a material such as a self-assembled monolayer (SAM) material 602 that can later be treated so as to form an oxide like material. This layer 602 is a material that will cause an oxide to selectively grow on it, and for purposes of simplicity will be referred to herein simply as a segregant promoter 602. The segregant promoter 602 is preferably applied very thin and may be (but is not necessarily) a mono-layer. The coating of the segregant promoter material 602 onto the stamp 402 can be accomplished by immersing the stamp 402 in a liquid or by exposing the stamp 402 to a vapor containing an appropriate precursor material. Then, as illustrated in FIG. 7, the stamp 402 is pressed against the seed layer 306 to print the segregant promoter material 602 onto the seed layer 306 in a specific pattern. This selectively deposits the segregant promoter 602 onto the seed layer 306 only at the locations of the raised portions 404 of the stamp, leaving selectively deposited segregant promoter 602 on the seed layer 306 as shown in FIGS. 8 and 9, wherein FIG. 8 shows a cross sectional view and FIG. 9 shows a top down view as seen from line 9-9 of FIG. 8.

The segregant promoter 602 can be a hydrocarbon polymer with silane and thiol termination such as HS—(CH₂)ₙ—Si(X)₃, where n>2, and X is Cl or OCH₃. The stamp 402 can be constructed of SiO₂/polydimethylsiloxane (PDMS) (as will be discussed below). The segregant promoter layer 602 which can be a thiol-terminated organosilane may be deposited onto the SiO₂/PDMS stamp surface by either wet chemical or dry vapor-phase methods. In the wet chemical method, the stamp is dipped into a 1 mM solution of the organosilane in toluene. Extra physisorbed and unattached molecules are removed by repeated rinsing in pure toluene. Vapor phase silylation is performed at 100 degrees C. in a vacuum oven. If necessary to remove excess material, the vacuum can be maintained for additional time in order to evaporate extra physisorbed molecules from the surface.

If the segregant promoter material 602 is a self-assembled monolayer such as that described above, the patterned segregant promoter 602 can be converted to an oxide like state through a UV/ozone exposure process. Such a process is illustrated by Y. Zhang, et al., J. Am. Chem. Soc., vol. 120 pp. 2654-2655 (1998), which is incorporated herein by reference. UV/ozone cleaning ovens (e.g. UVOCS) may be used for initial tests. UV tools currently used for lubricant bonding in media manufacturing may be used with nitrogen purge turned off and with ventilation installed for ozone disposal. Other materials 602, and other conversion methods, such as exposure to plasma, electrons or heat may also be used, as long as a chemical contrast pattern is produced that causes selective growth of the media segregant around the islands of magnetic film in the target pattern.

Optionally, the exposed seed layer 306 can be cleaned or reduced to remove an oxide layer. This can be accomplished by light sputtering or ion milling. These processes, however, may not be sufficiently selective so they must be carefully performed so as not to damage or remove the segregant promoter layer 602. Another option is exposure to H⁺ plasma, which can reduce oxidized metals back to the metallic state, but may be selective enough not to damage the patterned segregant promoter material 602.

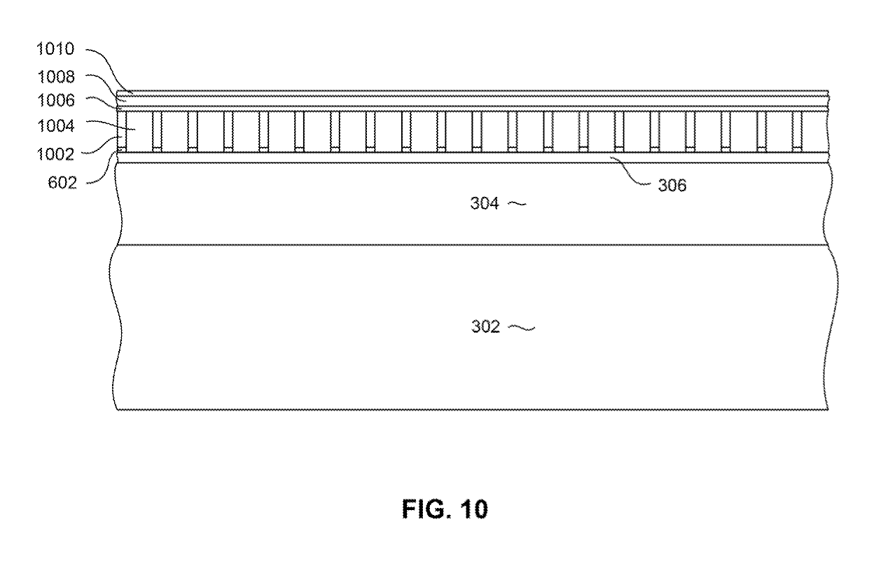

With reference now to FIG. 10, media growth proceeds with co-sputtering of magnetic alloy 1004 and segregant 1002. That is, both a magnetic alloy 1004 and a segregant 1002 are simultaneously sputter deposited in a sputter deposition tool. The magnetic alloy 1004 can be alloy containing Co and Pt or and the segregant 1002 can be and oxide such as SiO₂. The segregant 1002 grows preferentially over the patterned segregant promoter 602, and the magnetic alloy 1004 forms islands that grow only over the exposed seed layer 306. The net result is that the anti-dot pattern stamped on the disk with the segregant promoter 602 is replicated in the growth of the magnetic alloy 1004 and co-sputtered segregant 1002. The magnetic alloy 1004 grows as isolated islands over the exposed seed layer 306, and the segregant 1002 grows on the anti-dot pattern, forming a network around these islands. Both materials (magnetic alloy 1004 and segregant 1002) grow substantially vertically from the template, exposing both materials with the proper pattern at the newly formed upper surface.

The magnetic alloy 1004 (which can be referred to as a “storage layer” since it stores the magnetic bit of information) can actually include various magnetic materials. For example, the magnetic material 1004 can be several layers of materials each having different magnetic properties, such as each having a different magnetic coercivity. The magnetic layer 1004 can be constructed as a multi-layer structure with fine laminations of CoPt and/or CoPd. The magnetic layer 1004 can also be constructed as an exchange spring structure with a high magnetic coercivity layer, a low magnetic coercivity layer and a thin, non-magnetic coupling layer between the high and low coercivity layers. Again, whatever structure is used for layer 1004, this magnetic material is deposited simultaneously (co-sputtered) with the segregant material 1002.

With continued reference to FIG. 10, after the magnetic alloy 1004 and segregant 1002 have been deposited as described above, other media layers can be deposited. These can include an exchange control layer 1006 deposited over the magnetic alloy 1004 and segregant 1004, a capping layer 1008 can be deposited over the exchange control layer 1006 and an optional protective layer 1010 formed over the capping layer 1008. The exchange control layer can be a material such as Ru. The capping layer 1008 can be an alloy containing Co and other materials. The protective coating layer 1010 can be a physically hard material such as Diamond-Like Carbon (DLC) and serves to protect the under-lying layers from damage during operation of the media in a disk drive, such as from damage that might occur from head disk contact (e.g. crashing).

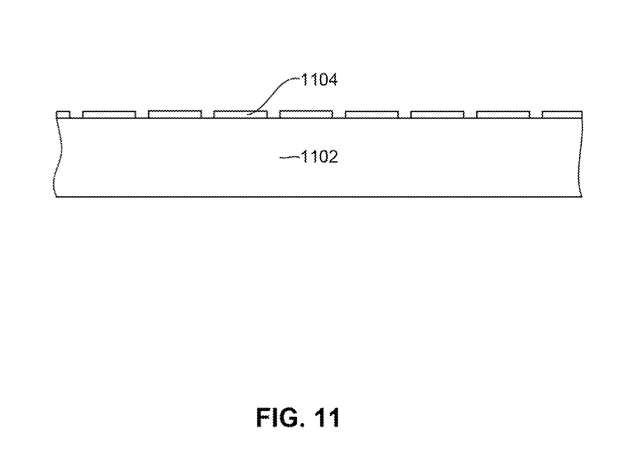

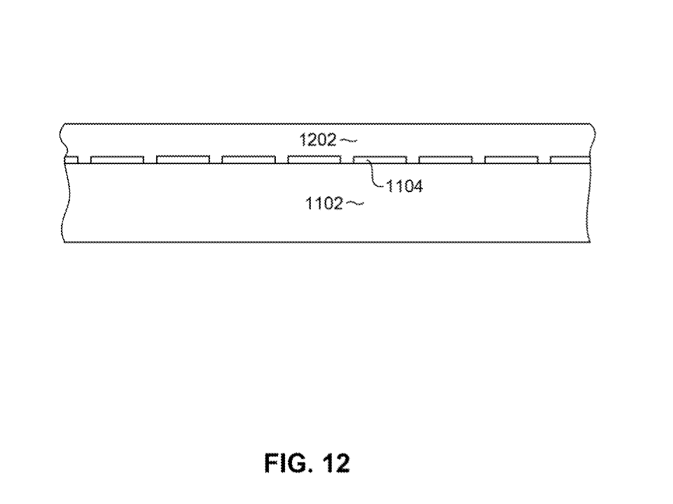

FIGS. 11 and 12 illustrate a possible method for constructing a stamp, such as the stamp 402 of FIG. 5. This is, however, by way of example, as other methods could be used to construct such a mask. With reference to FIG. 11, a master substrate 1102 is provided. This could be a Si substrate. A relief pattern is then formed on the surface of the substrate. One way to accomplish this is to pattern a material 1104 of desired thickness over the surface of the substrate 1102. This material 1104 can be lithographically patterned such as by etching or some other process. This patterned material, could be, for example, SiO₂, Si₃N₄, a metal, photoresist, or wax. As can be seen, this provides a relief pattern having raised portions and recessed portions. This pattern of raised and recessed portions is a negative image of the desired pattern of the completed stamp. This negative pattern could also be formed in other ways, such as by masking and then performing a reactive etching or ion milling to remove exposed portions of the substrate material 1102.

Then, with reference to FIG. 12, a material 1202 that will become the stamp is coated onto the master die layers 1102, 1104. This material 1202 can be a liquid silicone rubber precursor material such as PDMS precurser. A thermal or UV curing process can then be performed to form the material 1202 into a solid stamp structure, which can then be lifted off of the master (1102, 1104).

It should be pointed out, that the above process has been discussed as specifically applied to constructing a magnetic media for magnetic date recording. However, the process of selectively co-sputtering an array of structures from a stamp printed base material can also be used in other applications as well. For example, such a method can be useful in the construction of an array of cells of in a nonvolatile cross-point memory. Other examples of possible applications include the formation of array of cells of a phase change material in a dielectric matrix, such as might be useful in the construction of a memory cell. The process could also be applied to the construction of an array of cells of a memristor material in a dielectric matrix, which could also be useful in the construction of a memory cell array. The process could also be useful in the construction of an array of electrically conductive vias in a dielectric matrix or to the construction of an array of Magnetic Random Access Memory (MRAM) cells in a dielectric matrix. In order for the above described process to be effectively implemented, the structures being constructed should be fairly uniformly distributed over an area of interest, and all of the features should be below a critical feature size. The above segregation only occurs over a certain limited length scale.

Bit Patterned Media Fabricated by Templated Growth from a Printed Topographic Pattern:

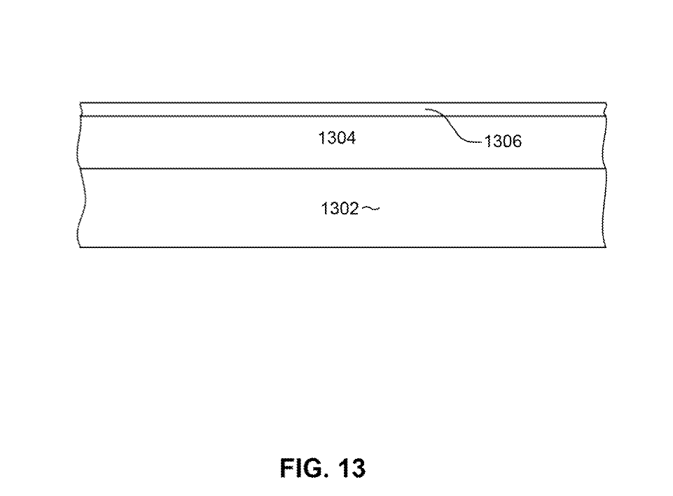

FIGS. 13-19 illustrate an alternate method for manufacturing a patterned media for magnetic data recording. This method defines a pattern of magnetic islands surrounded by non-magnetic segregants, wherein the growth of the magnetic and non-magnetic layers is defined by a topographic pattern.

In the previously discussed process, the growth of magnetic islands was based on the idea that “wetting” (or very loosely “epitaxy) could control where the magnetic material verses oxide would grow during co-sputtering. Once a pattern of metal islands surrounded by oxide was created, continued sputtering resulted in the oxide preferring to grow on the pre-existing oxide, and the metal on the pre-existing metal. A process will now be discussed which relies on a completely different growth mechanism. Instead of using a chemical contrast to initiate a desired growth pattern, this embodiment relies on “nucleation” of the magnetic islands as specific locations. Although all of the details are not understood, it has been found that grains can nucleate on topographic features on a substrate, and this nucleation can be used to initiate magnetic island growth at desired locations. In this invention, one can form raised islands on a substrate, and during co-sputtering of a magnetic material and a segregant, the magnetic metal will tend to grow at these raised islands which form nucleation sites.

With particular reference to FIG. 13, a substrate 1302 is provided. As before, the substrate 1302 can be a glass substrate or aluminum alloy that has been polished to have a very smooth surface. A soft magnetic layer 1304 is deposited over the substrate 1302, and an exchange break layer 1306 is deposited over the soft magnetic layer 1304. The soft magnetic layer and the exchange break layer 1306 can be deposited by sputter deposition. The soft magnetic layer 1304 and exchange break layer 1306 are optional, but are usually included in a perpendicular magnetic recording media. Also, other additional layers (not shown) may be included as well, such as layers that are deposited to provide a desired grain growth in the layers, or layers within the soft under-layer 1304 to create an anti-parallel coupled structure within the soft under-layer 1304.

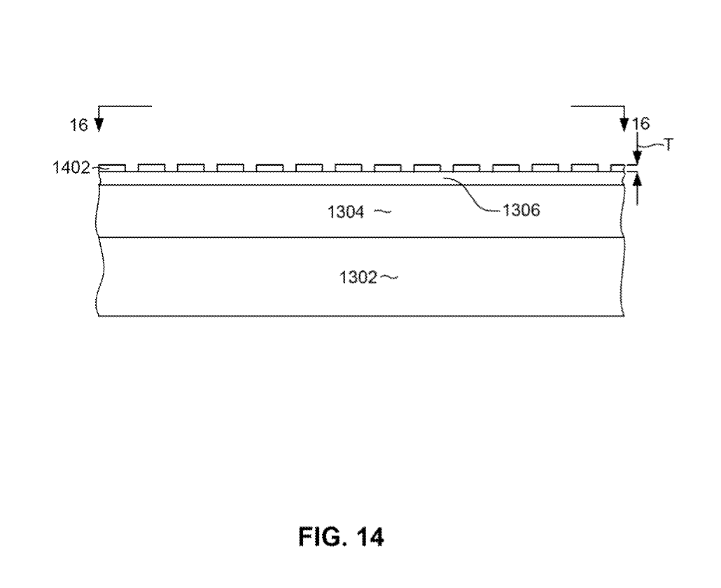

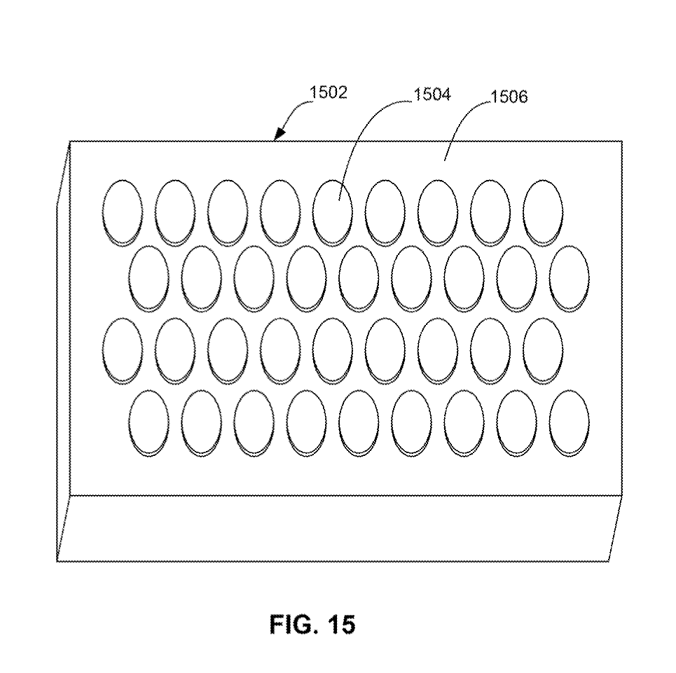

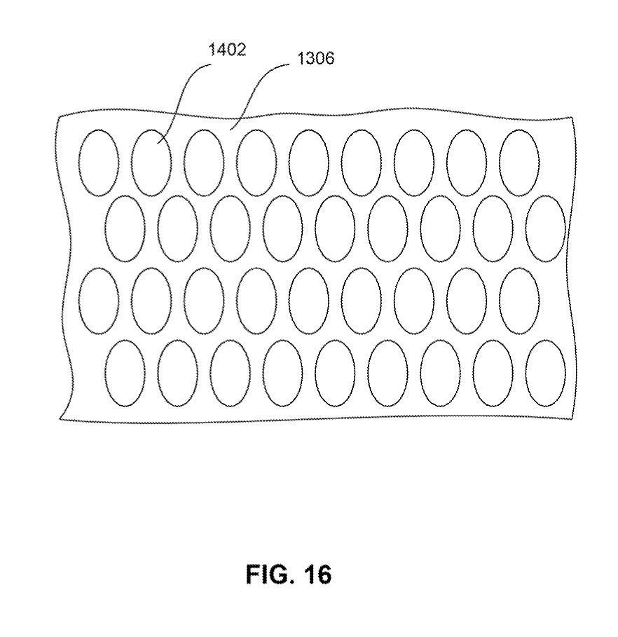

Then, with reference to FIG. 14, a topographic pattern layer 1402 is patterned onto the disk (e.g. over layer 1306 in FIG. 14) to form an array of raised regions 1402, separated by a recessed region. This layer 1402 can be formed by microcontact printing, as described above. However, the pattern of the layer 1402 is a negative image of the previously described pattern, in that the layer 1402 is a pattern of islands surrounded by spaces. This can be seen more clearly in FIG. 16, which shows a top down view as seen from line 16-16 of FIG. 14. This printing can be performed using a stamp 1502 that is shown in perspective view in FIG. 15. As can be seen, the stamp 1502 has raised islands 1504 that are surrounded by recessed spaces 1506. As can be seen, this is a negative image of the stamp described above with reference to FIG. 5. With reference again to FIG. 14, the layer 1402 preferably has a thickness T of 1-5 nm.

As before, the layer 1402 can be formed of a thiol-terminated organosilane, which can be post-processed via exposure to ultraviolet light (UV), heat, or plasma to convert the dot patterned layer 1402 into an oxide-like material. However, in this case, other materials could be used as well, since this process relies primarily on the topography of the layer 1402 as will be seen. Also, it is not necessary that the layer 1402 be patterned by microcontact printing. For example, the layer 1402 could also be formed by nanoimprinting a UV or heat curable polymeric material to form a protruding island patterned. If nanoimprinting is used, the nanoimprint template (or mold) will have a hole pattern rather than an island pattern (since nanoimprinting produces an inverse image of its mold). If nanoimprinting is used, a thin skin (or “residual layer”) may be formed between the protruding islands. This skin layer is acceptable and may be left in place. The pattern could also be formed by etching into an under-layer (rather than depositing a patterned layer).

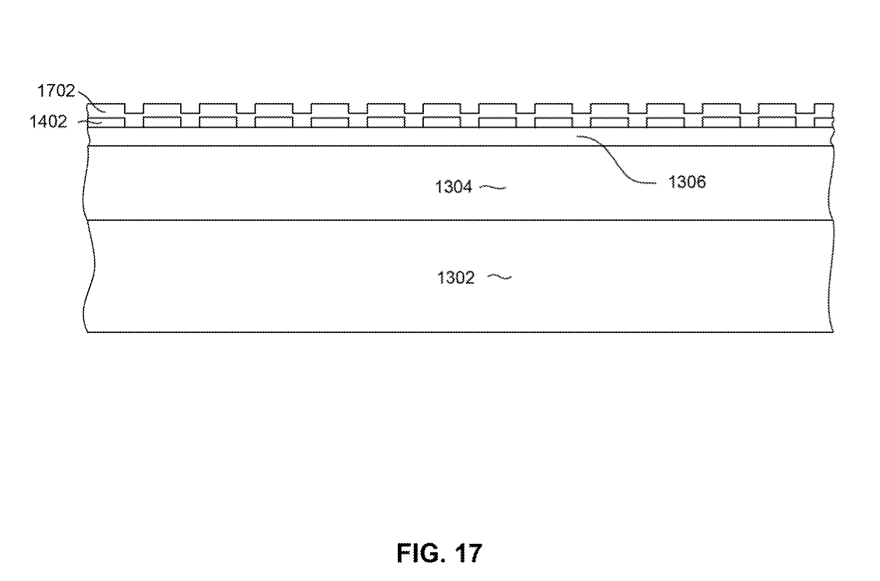

With reference now to FIG. 17 a seed layer 1702, constructed of a material such as Ru is deposited, which can be deposited by low pressure sputtering. The seed layer 1702 is optional, but can be beneficial in promoting a proper orientation of the magnetic material to be deposited in the next step, so that the magnetic material has target values of coercivity and magnetic moment. The topography that was previously patterned with reference to FIG. 14 will generally persist on the surface of the seed layer 1702. The seed layer 1702 can be a single layer, but may also be constructed as multiple layers. This depends upon design goals such as proper grain growth of the magnetic layer (yet to be deposited) to achieve target specifications.

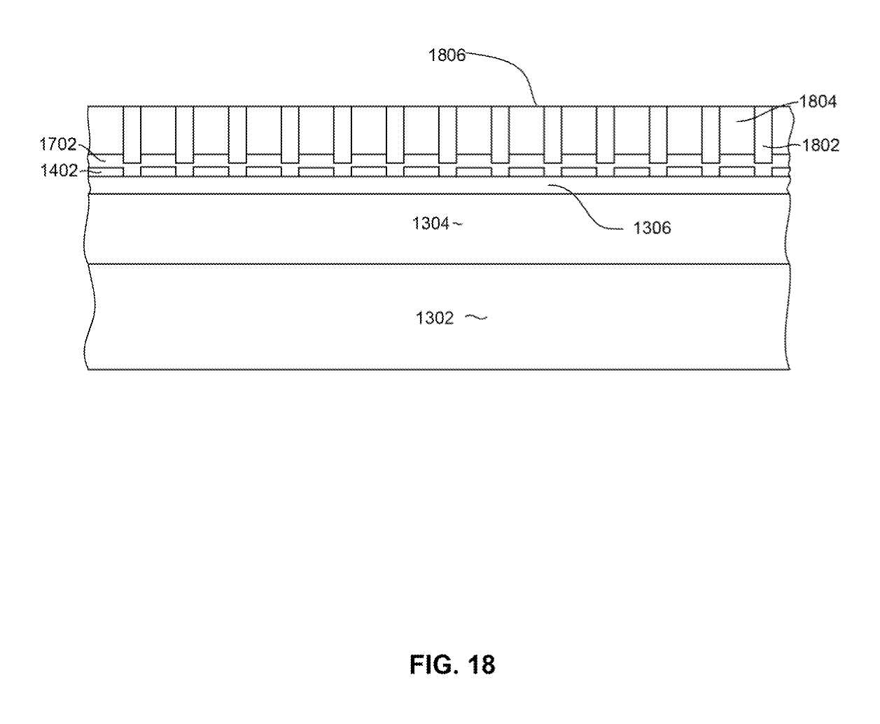

With reference now to FIG. 18, a magnetic alloy 1804 and a non-magnetic segregant 1802 are simultaneously co-sputtered in a sputter deposition tool. The magnetic alloy 1804 can be a material such as a Co—Pt—Cr alloy, and the non-magnetic segregant 1802 can be a material such as SiO₂. Given the sequence of steps described above, this co-sputtering will result in the magnetic alloy 1804 being preferentially deposited on the protruding islands and the segregant 1802 filling the space between the magnetic islands. Little or no segregant 1802 is deposited within the island, leaving unified, single domain magnetic islands. Although the islands may be multiple magnetic grains, there is insufficient segregant within an island to allow domain walls within the island. Any grains within the island are strongly exchange coupled.

The raised islands 1402 provide nucleation sites, where the growth of the magnetic alloy 1804 initiates. Although the islands 1402 are shown as having the same general size and shape as the finished magnetic islands, it is possible that a much smaller feature (such as a tiny protruding asperity or point) could be used instead. The process would be the same, initiating the growth of magnetic islands separated by non-magnetic segregant. That would provide a well defined single point where the magnetic grain structure could start growing, and it would grow outward from there.

When using larger topographic islands 1402 like those shown, it is not clearly understood where exactly the growth nucleates on the island, and it is not known whether the growth self-terminates at the island edges. It is known, however, that this growth on these islands works to form a well-defined pattern of magnetic islands. Surprisingly, and unexpectedly, this growth on a topographically patterned substrate works even better than the previously described growth over a chemical contrast pattern. It should also be pointed out that both of these processes (chemical contrast and topographic patterns) could be used together rather than separately as shown here.

The original topography of the protruding island pattern created previously with reference to FIG. 14 and replicated in the process described with reference to FIG. 17 may or may not appear at the surface 1806 when the co-sputtering is completed. The preferential deposition of alloy 1804 on the islands and segregant 1802 into the spaces between tends to reduce this topography, in some cases even to the point of virtually planarizing the structure. This is beneficial, since reduced topography provides a better head-disk interface for better flying of the air bearing slider and reduction of vulnerability to corrosion (since subsequent overcoat conformity is improved).

The magnetic material 1804 may be a single layer with a single alloy, or it may be multiple layers with varying magnetic properties. A very thin non-magnetic layer may be included along with magnetic layers. Periodic multi-layers, such as Co—Pd may be used. In all of these cases, the magnetic layer or layers are co-sputtered along with the nonmagnetic segregant, at least for some of the layers.

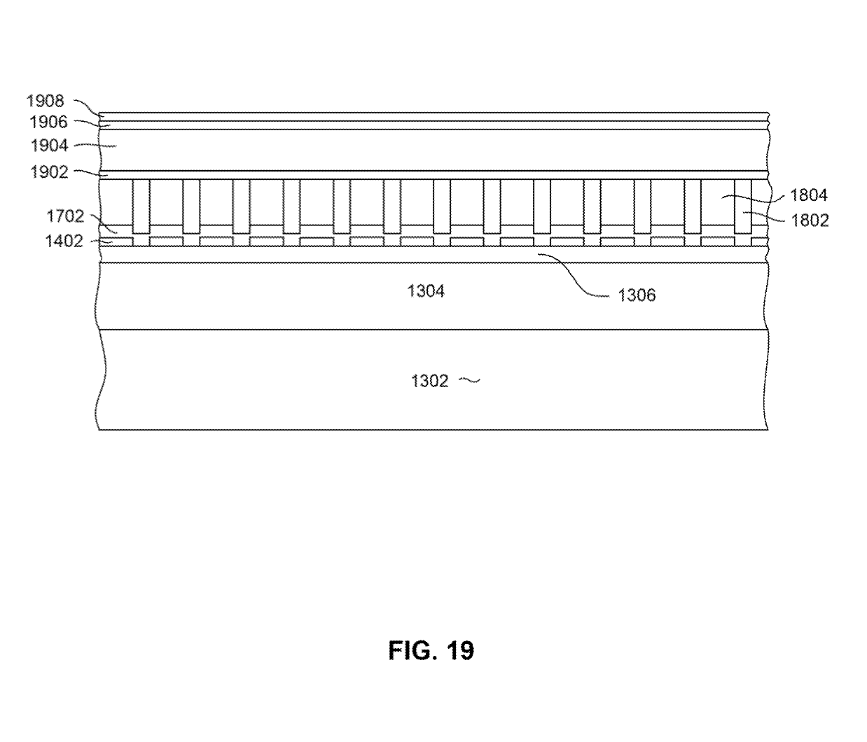

With reference now to FIG. 19 after the co-sputtering of layers 1802, 1804 has been completed, an exchange control layer 1902 can be deposited, followed by a capping layer 1904 and a protective overcoat 1906. The exchange control layer 1902 and capping layer 1904 are optional. The presence of the exchange control layer 1902 and capping layer can provide the following advantages. First, they can introduce a controlled amount of exchange coupling between the magnetic islands 1804. Secondly, they can provide an exchange spring function to improve write-ability while allowing the use of a higher coercivity magnetic alloy in the magnetic islands 1804 for better thermal stability. The protective overcoat 1906 can be a material such as diamond-like carbon. After deposition of the protective layer 1906, a lubricant layer 1908 can be deposited.

While various embodiments have been described above, it should be understood that they have been presented by way of example only and not limitation. Other embodiments falling within the scope of the invention may also become apparent to those skilled in the art. Thus, the breadth and scope of the invention should not be limited by any of the above-described exemplary embodiments, but should be defined only in accordance with the following claims and their equivalents.

What is claimed is:

1. A method for manufacturing a self-assembled patterned structure, comprising:
forming a patterned topography that includes an array of raised portions surrounded by a recessed region, the array of raised portions being formed by applying a material to an under-lying surface; and
simultaneously co-sputter depositing a magnetic alloy and a non-magnetic material.

2. The method as in claim 1 wherein the array of raised portions comprises an array of raised islands.

3. The method as in claim 1 wherein the array of raised portions comprises an array of elliptical islands.

4. The method as in claim 1 further comprising, after forming the patterned topography and before co-sputtering the magnetic alloy and non-magnetic material, depositing a seed layer.

5. The method as in claim 4 wherein the seed layer comprises Ru.

6. The method as in claim 4 wherein the deposition of the seed layer comprises low pressure sputtering of Ru.

7. The method as in claim 1 wherein the raised regions have a height of 1 to 5 nm as measured from the recessed region.

8. The method as in claim 1 wherein the material is applied to the under-lying surface by micro-contact printing.

9. The method as in claim 1 wherein the material is applied to the under-lying surface by nano-imprinting.

10. The method as in claim 1 wherein the material applied to the under-lying surface is a thiol-terminated organo silane that is applied by micro-contact printing.

11. The method as in claim 1 wherein the magnetic alloy comprises Co—Pt—Cr.

12. The method as in claim 1 wherein the nonmagnetic segregant comprises an oxide.

13. The method as in claim 1 wherein the nonmagnetic segregant comprises SiO₂.

14. The method as in claim 1 wherein the magnetic alloy comprises Co—Pt—Cr and the non-magnetic segregant comprises an oxide.

15. The method as in claim 1 wherein the magnetic alloy comprises Co—Pt—Cr and the non-magnetic segregant comprises SiO₂.

16. A method for manufacturing a self-assembled patterned structure, comprising:
providing a substrate;
using a stamp to print a topographic pattern over the substrate, the topographic pattern comprising an array printed material; and
co-sputtering a magnetic alloy and a non-magnetic segregant.

17. The method as in claim 16 wherein the stamp includes an array of raised portions separated by a recessed portion.

18. The method as in claim 16 wherein the printed material has a thickness of 1-5 nm.

19. The method as in claim 16 wherein the printed material comprises a thiol-terminated organo silane.

20. The method as in claim 19 further comprising exposing the printed material to ultraviolet light (UV), heat, or plasma to convert the printed material to an oxide like material.

21. The method as in claim 1 wherein the self-assembled patterned structure is a bit patterned magnetic media.

22. The method as in claim 19 wherein the self-assembled patterned structure is a bit patterned magnetic media.

23. A method for manufacturing a magnetic medium for magnetic data recording, comprising:
forming a patterned topography that includes an array of raised portions surrounded by a recessed region; and
simultaneously co-sputter depositing a magnetic alloy and a non-magnetic material.

24. The method as in claim 23 wherein the patterned topography is formed by applying a material to an underlying surface.

25. The method as in claim 23 wherein the patterned topography is formed using a stamp to apply a material to an underlying surface such that the applied material forms the array of raised portions.

26. The method as in claim 23 further comprising, after forming the patterned topography and before co-sputtering the magnetic alloy and non-magnetic material, depositing a seed layer.

27. The method as in claim 23 wherein the non-magnetic segregant comprises an oxide.

28. The method as in claim 26 wherein the seed layer comprises Ru.

29. The method as in claim 23 wherein the magnetic alloy comprises Co—Pt—Cr and the non-magnetic segregant comprises an oxide.
